(19) United States
(12) Patent Application Publication
(10) Pub. No.: US 2003/0121056 A1
(43) Pub. Date: Jun. 26, 2003

(54) HFC reverse path using an intelligent dynamic switch

(76) Inventors: Donald C. Sorenson, Lawrenceville, GA (US); David M. Job, Lawrenceville, GA (US); Lamar E. West JR., Maysville, GA (US)

Correspondence Address: SCIENTIFIC-ATLANTA, INC., INTELLECTUAL PROPERTY DEPARTMENT, 5030 SUGARLOAF PARKWAY, LAWRENCEVILLE, GA, 30044, US

(21) Appl. No.: 10/026,283

(22) Filed: Dec. 21, 2001

(51) Int. Cl. H04B 17/00; H04N 7/173; H04L 1/00; H03D 1/04; H03D 1/06; H04B 1/10; H03K 5/01; H03K 6/04; H04L 25/08; H04N 5/21; H04N 5/213; H04N 5/217

(52) U.S. Cl. 725/125; 375/346; 348/607; 455/67.3

(57) ABSTRACT

The present invention provides an apparatus and method for reducing the amount of ingress noise that is present in the reverse path of a two-way communication network. The present invention employs intelligent dynamic switches (200) that determine whether desirable reverse signals are present at that point in the network. If so, the reverse signals, which also probably include some amount of ingress noise, are allowed to pass further upstream. If no desirable reverse signals are present at that point in the network, the IDS (200) blocks the transmission of any reverse signal further upstream, thereby blocking the transmission of any ingress signals. Although ingress noise is allowed to travel upstream with desirable reverse signals, the performance of the overall network is improved because ingress signals are blocked at various points in the network, thereby reducing the total amount of cumulative ingress noise signals that would otherwise be present in the network.

### FIELD OF THE INVENTION

This invention relates generally to broadband communications systems, such as cable television networks, and more specifically to an intelligent dynamic switch that controls the transmission of reverse path radio frequency (RF) signals that are generated in the broadband communications network.

### BACKGROUND OF THE INVENTION

FIG. 1 is a block diagram illustrating an example of one branch of a conventional broadband communications system, such as a two-way hybrid/fiber coaxial (HFC) network, that carries optical and electrical signals. Such a network may be used in a variety of systems, including, for example, cable television networks, voice delivery networks, and data delivery networks to name but a few. The communications system 100 includes headend equipment 105 for generating forward, or downstream, signals (e.g., voice, video, or data signals) that are transmitted to subscriber equipment 145. Initially, the forward signals are transmitted as optical signals along a first communication medium 110, such as a fiber optic cable. In most networks, the first communication medium 110 is a long haul segment that carries light having a wavelength in the 1550 nanometer (nm) range. The first communication medium 110 carries the forward signal to hubs 115, which include equipment that transmits the optical signals over a second communication medium 120. In most networks, the second communication medium 120 is an optical fiber that is designed for shorter distances, and which carries light having a wavelength in the 1310 nm range.

From the hub 115, the signals are transmitted to an optical node 125 that converts the optical signals to radio frequency (RF), or electrical, signals. The electrical signals are then transmitted along a third communication medium 130, such as coaxial cable, and are amplified and split, as necessary, by one or more distribution amplifiers 135a-c positioned along the communication medium 130. Taps 140 further split the forward signals in order to provide signals to subscriber equipment 145, such as set-top terminals, computers, telephone handsets, modems, televisions, etc. It will be appreciated that only one branch of the network connecting the headend equipment 105 with the plurality of subscriber equipment 145 is shown for simplicity. However, those skilled in the art will appreciate that most networks include several different branches connecting the headend equipment 105 with several additional hubs 115, optical nodes 125, amplifiers 135a-c, and subscriber equipment 145.

In a two-way network, the subscriber equipment 145 can also generate reverse RF signals, which may be generated for a variety of purposes, including email, web surfing, pay-per-view, video on demand, telephony, and administrative signals from the set-top terminal. These reverse RF signals are typically in the form of modulated RF carriers that are transmitted upstream through the reverse path to the headend equipment 105. The reverse electrical signals from various subscribers may be combined via the taps 140 and passive electrical combiners (not shown). Reverse electrical signals may also be combined with other reverse signals and amplified by one or more of the distribution amplifiers 135a-c. The reverse electrical signals are typically converted to optical signals by the optical node 125 before being provided to the headend equipment 105. It will be appreciated that in the electrical, or RF, portion of the network 100, the forward and reverse electrical signals are carried along the same coaxial cable 130. In contrast, the forward and reverse optical signals on the first and second communications media 110, 120 are usually carried on separate optical fibers.

In addition to the desired reverse RF signals that are transmitted by the subscriber equipment, undesired electrical noise or interference can enter the network at any time, regardless of whether a desired reverse RF carrier signal is being transmitted. Such noise or interference is referred to as ingress signals or ingress noise, and may be transmitted along the reverse path along with the intended reverse path signals. Once present in the network, the undesired RF ingress signals are transmitted back through the HFC reverse path along with the desired RF carrier(s). These undesired RF ingress signals can interfere with the desired RF signals. Of particular concern is the fact that the undesired RF signals from multiple premises tend to be combined and, therefore, to build in relative amplitude. The aggregate of these undesired RF signals can pose a considerable threat to the ability of the network to successfully transmit the desired RF carriers.

As a result of the problems associated with ingress noise, a great deal of effort has been devoted to understanding, quantifying, and controlling ingress. Studies have shown that the majority of ingress originates at or around the subscribers' premises. For example, large portions of the reverse ingress signals enter the network through defective connectors and poorly shielded cable and components, which are frequently found in use with subscriber equipment. The ingress signals may be caused by electric motors, radio transmitters, CB radios, automobile ignitions and other sources that are found in proximity to subscriber premises. Unfortunately, however, ingress signals vary substantially from network to network, from day to day, and from hour to hour.

It will also be appreciated that although noise signals travel along both the forward and reverse paths, ingress signals present significantly greater problems in the reverse path because ingress signals typically originate in a frequency band that coincides with the HFC return band, which ranges from 5 MHz to 42 MHz. In addition, the reverse ingress signals are funneled and aggregated in the reverse path as they move toward the headend facility.

The present invention is, therefore, directed to a product and a method that reduces the ingress signals that have entered the coaxial distribution reverse path. As a result, the HFC network's reverse path signaling capacity, quality, and reliability are greatly enhanced.

### BRIEF DESCRIPTION OF THE DRAWINGS

FIG. 1 illustrates an example of one branch of a conventional broadband communications network, such as a two-way HFC cable television network, that carries optical and electrical signals.

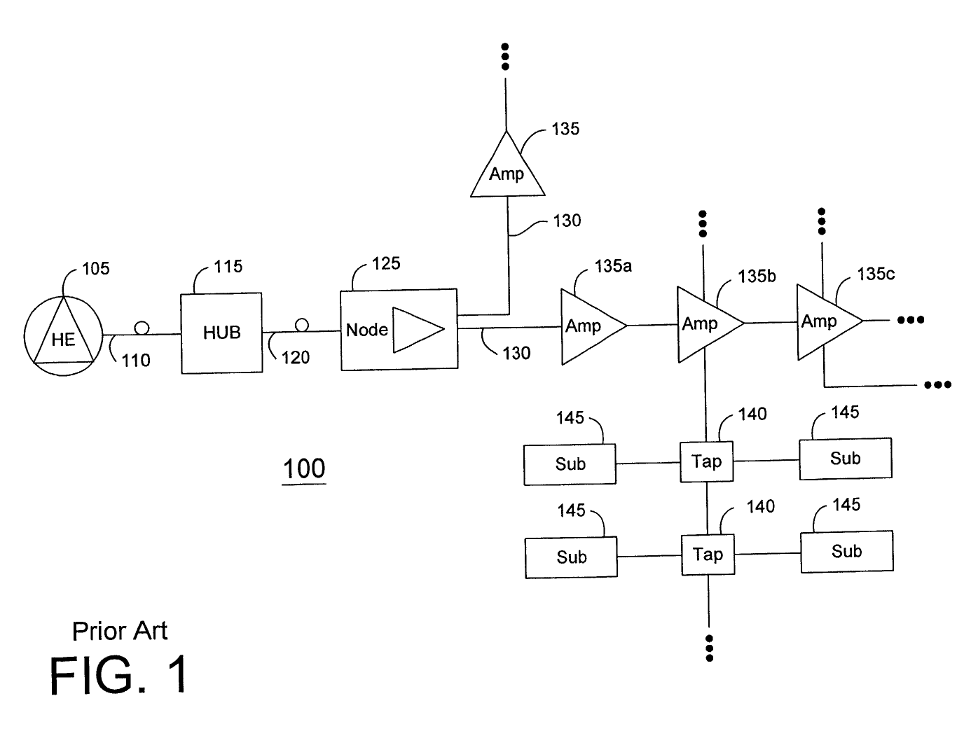

FIG. 2 is a block diagram of an intelligent dynamic switch in accordance with the present invention that controls the transmission of reverse RF signals in the reverse path of the broadband communications network of FIG. 1.

FIG. 3 illustrates an example of one branch of a communications network that includes a plurality of intelligent dynamic switches in accordance with the present invention.

FIG. 4 illustrates a typical reverse band and the frequencies allocated to various services that may be used by the subscriber equipment for the purpose of sending reverse carrier signals.

### DETAILED DESCRIPTION OF A PREFERRED EMBODIMENT

The present invention will be described more fully hereinafter with reference to the accompanying drawings in which like numerals represent like elements throughout the several figures, and in which exemplary embodiments of the invention are shown. This invention may, however, be embodied in many different forms and should not be construed as being limited to the embodiments set forth herein; rather, the embodiments are provided so that this disclosure will be thorough and complete, and will fully convey the scope of the invention to those skilled in the art. For example, although the present invention is described in the context of a reverse path of a two-way communications network, the present invention is not limited to the reverse path and reverse signals. Furthermore, although the reverse RF carrier signals are typically modulated with data signals originating at the subscriber equipment, these RF carrier signals could also include additional types of signal modulation, such as voice or video. Moreover, the present invention can be embodied in a stand-alone product or included within a conventional communications device. The present invention is described more fully hereinbelow.

Generally described, an intelligent dynamic switch (IDS) in accordance with the present invention reduces the problem of reverse ingress by allowing a reverse signal to proceed further along the reverse path only if a desired reverse signal is present. The IDSs will be deployed at a variety of points in the network. If an IDS determines that no desired reverse signal is present at that point in the network, it will prevent the transmission of any reverse signal, thereby preventing the transmission of reverse ingress signals beyond that point in the network.

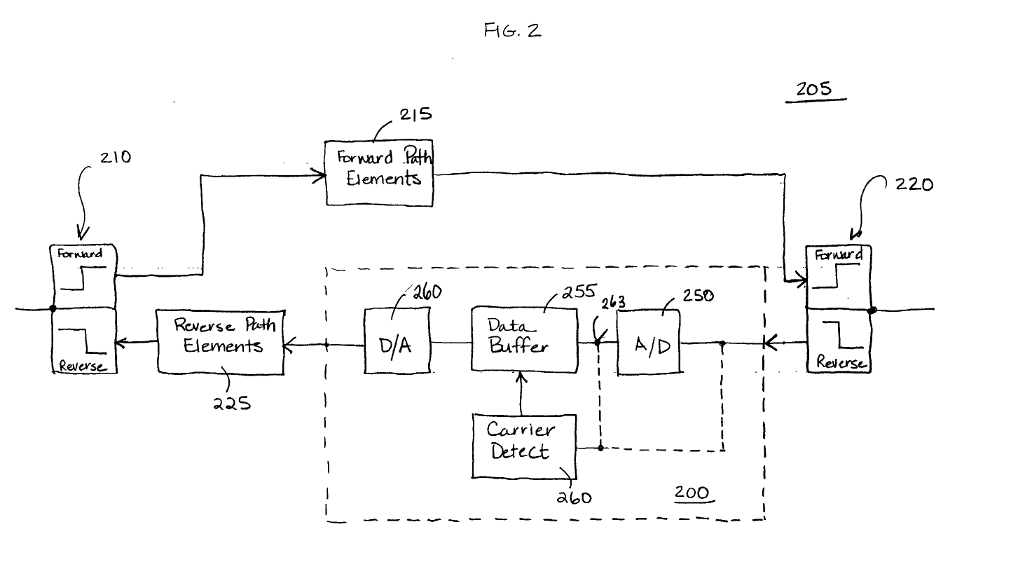

The basic elements of an exemplary IDS are shown in the block diagram of FIG. 2. The concept proposed herein uses an intelligent switch to allow transmission of reverse RF signals only when the IDS 200, which may form a portion of communication device 205, detects a reverse RF carrier signal. As shown in FIG. 2, there are four main elements related to the present invention. They are:

1) Optionally, converting reverse RF signals received at the IDS 200 to digital signals that represent the received RF signals.

2) Detecting when a reverse RF carrier signal is present (either prior to or subsequent to digitizing the reverse analog signals).

3) Delaying or buffering the digital signals.

4) Releasing the buffered signals only when at least one RF carrier signal is present.

5) Converting the digital signals back to analog signals.

FIG. 2 illustrated an embodiment in which the IDS 200 is included within a conventional communications device 205, such as a tap or amplifier. When the communications device 205 is used in the RF distribution network, forward and reverse signals are typically transmitted through the device 205. In this manner, a diplex filter 210 is used to separate the forward and reverse signals. A high pass filter isolates the forward signals, which are typically within a band that ranges from 50 MHz to 870 MHz, and provides the forward signals to conventional forward path elements 215 associated with the communication device 205. The forward signals then pass through diplex filter 220 before being transmitted further downstream in a conventional manner.

Reverse signals received at diplex filter 220 are filtered via a low pass filter and provided to the IDS 200. The reverse RF signals are passed from the IDS 200 to conventional reverse path elements 225 only after the IDS 200 determines that there is an RF carrier signal present within the reverse RF signals. A low pass filter in diplex filter 210 isolates the reverse signals from the forward signals and allows transmission upstream. It will be appreciated that the IDS 200 can also be a stand-alone product so long as appropriate diplex filters are used to isolate the forward and reverse signals in a two-way network.

In accordance with the operation described above, the IDS 200 only allows transmission of reverse RF signals when an RF carrier signal is present. This effectively blocks the transmission of ingress signals until such time as the IDS 200 allows the reverse RF signals to pass through. Significantly, this device and method reduces the ingress signals that conventionally are transmitted and aggregated continuously through the reverse path and are received at the headend, and is discussed in further detail below.

An Exemplary Embodiment of an Intelligent Dynamic Switch

As illustrated in FIG. 2, an embodiment of an IDS in accordance with the present invention includes an analog-to-digital converter 250, a data buffer 255, a carrier detect circuit 260, and a digital-to-analog converter 260. A description of the primary elements of the IDS 200 follows.

Analog-to-Digital Converter—250/Digital-to-Analog Converter—260

The A/D converter 250 receives a reverse analog RF signal that is a composite of one or more reverse RF carriers. The reverse RF signals originate with one or more of the subscribers that are located downstream from the communication device 205. Those skilled in the art will appreciate that if the communication device 205 is a tap, the number of subscribers downstream from the tap may be as few as two or four, and that if the communication device 205 is an amplifier, the number of subscribers downstream from the amplifier may be as high as several thousand. Those skilled in the art will also appreciate that the reverse band is typically from 5 MHz to 42 MHz in U.S. cable television networks, and from 5 MHz to 65 MHz in European cable television networks.

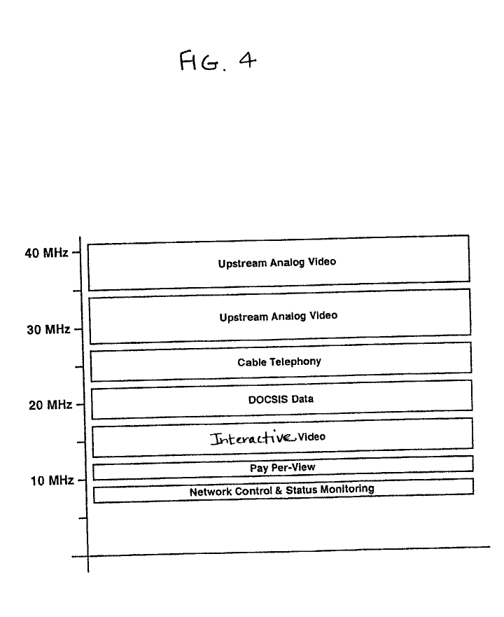

The composite RF signal received at the A/D converter 250 will include RF carrier signals if any of the subscriber equipment located downstream is sending signals back to the headend. The nature of the reverse service signals being transmitted back to the headend for processing depend upon the services that employ the reverse path, such as impulse pay-per-view (IPPV), video on demand, cable modem signals, etc. Commonly, carrier signals for different reverse services are sent in independent frequency bands. FIG. 4 illustrates an example of the reverse path frequency allocation where various sub-bands in the 5 MHz to 42 MHz reverse band are allocated to various services that are available to the subscriber equipment. The reverse carrier signals are transmitted to application devices, commonly known as service receivers, that are located in the headend facility.

It will be appreciated that digitization of an analog signal is known in the telecommunications industry and others, for example, as a means of converting a single baseband video or voice signal to a digital signal format. The conversions for these single signals, however, are accomplished using an A/D converter having a very low sampling rate. In contrast, reverse broadband communications signals used in a broadband cable television network require a significantly higher sampling rate. Those skilled in the art will be familiar with the Nyquist theory, which states an analog signal must be sampled at a frequency that is greater than twice the maximum signal bandwidth in order to ensure that all information can be extracted and the inherent aliasing will not corrupt the original signal. In a conventional HFC communications network, the A/D and D/A converters operate with a sampling clock of typically 100 MHz with a packet size of 10 or 12-bits. The need for a sampling rate of 100 Megasamples per second (Ms/s), which is essentially equivalent to a 100 MHz sampling clock, is determined by understanding that the reverse RF bandwidth in the U.S. ranges from 5 MHz to 42 MHz. The sampling rate, therefore, should be no less than 84 Ms/s, and is typically increased to 100 Ms/s because a practical anti-aliasing filter requires some transition bandwidth. A sampling rate of 150 Ms/s is used for a reverse band ranging from 5 MHz to 65 MHz. The higher sampling rate substantiates the requirement of a more robust and complex A/D and D/A converter to digitize the entire bandwidth of the HFC reverse path broadband signals compared to that required for a single signal.

Accordingly, the A/D converter 250 receives the reverse RF signals and digitizes the received RF waveform producing a signal that is represented by parallel digital bits. The digital output of the A/D converter 250 is then provided to data buffer 255.

Carrier Detect Device—260

The main function of a carrier detect device 260 in accordance with the present invention is to determine the presence of at least one desired RF carrier signal within the entire reverse bandwidth. In a preferred embodiment, a digital carrier detect device 260 determines the presence of at least one desired reverse RF carrier signal by examining the digitized reverse signal that is provided by the A/D converter 250. A digital carrier detect circuit may be implemented using a low-cost digital circuit that includes a few gates and counters. By way of example, desired RF carrier signals are detected when power level values of the reverse signal are above a certain threshold value for a predetermined period of time, such as 8 microseconds. For example, if 200 consecutive or nonconsecutive samples out of 800 samples are above the threshold value, then an RF carrier signal is detected. It will be appreciated that the threshold value, number of samples that are greater than the threshold value, and the period of time are adjustable dependent upon the requirements and environment that exist in the communications network. For example, the threshold value may be chosen depending upon the characteristics of the communication network by taking into consideration the signal-to-noise level and signal amplitude range, to name but a few.

Data Buffer—255

Data buffers are well known in the art and are easily designed depending upon their application. A low-cost digital data buffer that uses registers or random access memory (RAM) introduces a delay that is necessary to give the carrier detect circuit 260 sufficient time to detect the presence of a desired RF carrier signal. In a preferred embodiment of the digital data buffer 255, a 10-bit 800 samples stage first-in-first-out (FIFO) delay line 255 is used to introduce the delay. Once an RF carrier signal is detected, the carrier detect circuit 260 controls a switch 263 that allows the delayed digital signals to pass through the data buffer 255. The digital signals are provided to the D/A converter 260 where they are converted back to analog RF signals for processing by the conventional reverse path elements 225.

Communications Network Including a Plurality of IDSs

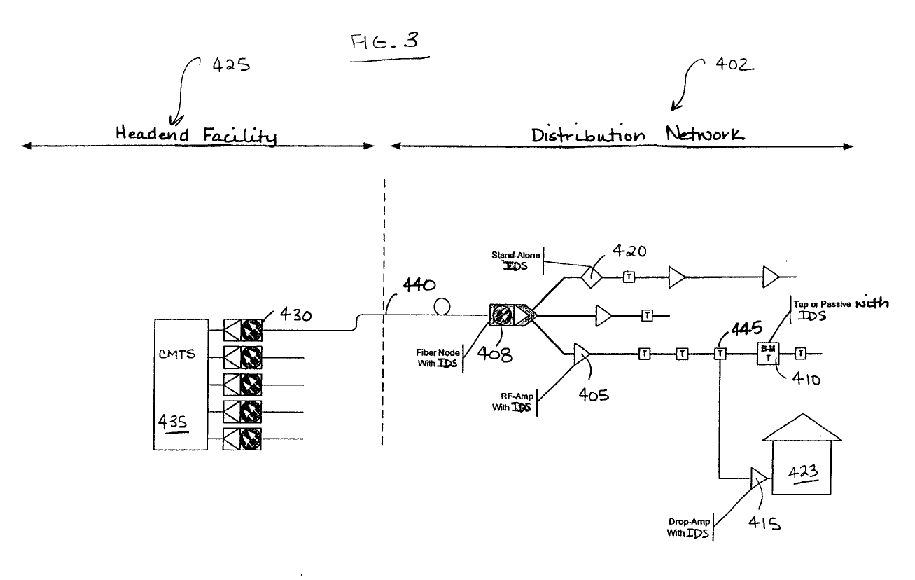

Referring now to FIG. 3, there is illustrated an example of one branch within a communications network including a plurality of IDSs 200 in accordance with the present invention that are located throughout the distribution network 402. The IDSs 200 can be located in RF amplifiers 405, optical nodes 408, distribution taps 410, and/or drop amps 415. Additionally, stand-alone IDSs 420 can also be included at various locations of the branches dependent upon operator preferences. These devices 405, 408, 410, 415, 420 operate according to the teachings mentioned hereinabove in that they only allow conventional processing of the reverse RF signals and further transmission upstream when a desired RF carrier signal is present. Preferably, the IDSs 200 should be located as far downstream in the various branches as economically feasible since that is the predominant place where ingress occurs.

Each IDS essentially blocks all reverse signals that originate downstream from its location and prevents further transmission upstream until that IDS receives a desired RF carrier signal. When the first IDS in a reverse branch, for example, IDS 415, receives a desired RF carrier signal from subscriber equipment within the subscriber premise 423, the IDS 415 allows transmission of the reverse RF signals upstream to the next IDS 405, which also detects the desired RF carrier signal and allows the signal to pass. IDS 408, after detection of the RF carrier signal, then allows transmission of the reverse RF signals to the headend facility 425. It will be appreciated that the optical node including an IDS 408 may be coupled to a plurality of branches and, therefore, blocks the transmission of reverse signals in all branches until at least one RF carrier signal is detected from at least one branch. Those skilled in the art will also appreciate that an optical node 408 will also convert to reverse RF signal into an optical signal for transmission to the headend facility 425 via optical fiber 440.

In headend facility 425, a reverse optical receiver 430 receives the optical signal that corresponds to the filtered reverse RF signals having at least one RF carrier signal. The reverse optical signal is converted back to an electrical signal in the optical receiver 430 and provided to an appropriate application device, such as a cable modem termination system (CMTS) 435. The received signals at the CMTS 435 include reverse RF carrier signals that are intended for that application device. Notably, according to the present invention, the desired reverse RF carrier signals have a significantly lower ingress signals as a result of one or more of the IDSs in the distribution network 402 not transmitting reverse signals without the presence of a desired RF carrier signal, thereby providing better signal quality. For example, if the subscriber equipment 423 is not transmitting a desired reverse signal, the IDS 415 will prevent the transmission of any signal, including any ingress that occurs at the subscriber's premises, from being transmitted upstream to tap 445.

From the foregoing description, it will be appreciated that the present invention provides an apparatus and method for reducing the amount of ingress noise signals that is present in the reverse path of a two-way communication network. The present invention employs intelligent dynamic switches that determine whether desirable reverse signals are present at that point in the network. If so, the reverse signals, which also probably include some amount of ingress noise, are allowed to pass further upstream. If no desirable reverse signals are present at that point in the network, the IDS blocks the transmission of any reverse signal from further transmission upstream, thereby blocking the transmission of any ingress noise signals. Although ingress noise is allowed to travel upstream with desirable reverse signals, the performance of the overall network is improved because ingress signals are blocked at various points in the network, thereby reducing the total amount of cumulative ingress noise that would otherwise be present in the network.

The present invention has been described in the relation to particular embodiments, which are intended in all respects to be illustrative rather than restrictive. For example, although the present invention has been described in the context of the reverse path of an HFC cable television network, those skilled in the art will understand that the principles of the present invention may be applied to, and embodied in, communications networks employing a variety of architectures and communications media. In addition, the present invention need not be limited to the reverse path.

Alternative embodiments will become apparent to those skilled in the art to which the present invention pertains without departing from its spirit and scope. Accordingly, the scope of the present invention is defined by the appended claims rather than by the foregoing description.

What is claimed is:

1. A method for reducing ingress signals in a communication network, comprising the steps of:
receiving an input signal, the input signal including at least one of a desirable signal and ingress signals;
determining if the input signal includes a desirable signal;
if the input signal includes a desirable signal, allowing the input signal to proceed through the communication network; otherwise, preventing the transmission of the input signal.

2. The method of claim 1, wherein the determining step comprises determining whether the input signal includes at least one RF carrier signal.

3. The method of claim 2, wherein determining whether the input signal includes at least one RF carrier signal comprises determining whether the signal power level exceeds a threshold level.

4. The method of claim 1, wherein the determining step comprises the steps of:
delaying the input signal for a predetermined period of time; and
determining whether the input signal includes at least one RF carrier signal during the predetermined period of time.

5. A dynamic switch for reducing the amount of ingress signals in a communication network, comprising:
an input for receiving a first RF input signal from a first portion of the communication network, the first RF input signal including at least one of a desirable input signal and an ingress signal;
an analog-to-digital converter for converting the first RF input signal to a digital input signal, the digital input signal including a plurality of digital input signal values;
a detector for determining whether the signal power level of the digital input signal exceeds a threshold value;
a buffer for temporarily storing the digital input signal values and for outputting digital input signal values when the detector determines that the signal power level of the digital input signal exceeds the threshold value;
a digital-to-analog converter for receiving the digital input signal values from the buffer and for converting the digital input signal values into a second RF input signal corresponding to the first RF input signal; and
an output for providing the second RF input signal to a second portion of the communication network,
whereby the second RF input signal is provided to the second portion of the communication network only when the detector determines that the signal power level of the digital input signal exceeds the threshold value.

6. In a cable television network including a forward path for transmitting signals from a headend to subscriber equipment and a reverse path for transmitting signal from the subscriber equipment to the headend, a dynamic switch for reducing the amount of reverse ingress noise in the reverse path of the cable television network, comprising:
an input for receiving a first analog reverse signal from a downstream portion of the cable television network, the first analog reverse signal including at least one of a desirable input signal and an ingress noise signal;
an analog-to-digital converter for converting the first analog reverse signal to a digital reverse signal, the digital reverse signal including a plurality of digital reverse signal values;
a detector for determining whether the signal power level of the digital reverse signal exceeds a threshold value;
a buffer for temporarily storing the digital reverse signal values and for outputting digital reverse signal values when the detector determines that the signal power level of the digital reverse signal exceeds the threshold value;
a digital-to-analog converter for receiving the digital reverse signal values from the buffer and for converting the digital reverse signal values into a second analog reverse signal corresponding to the first analog reverse signal; and
an output for providing the second analog reverse signal to an upstream portion of the cable television network,
whereby the second analog reverse signal is provided to the upstream portion of the cable television network only when the detector determines that the signal power level of the digital reverse signal exceeds the threshold value.

7. In a broadband communications network having forward and reverse paths for transmitting forward and reverse RF signals, respectively, the reverse RF signals including ingress signals, the broadband communications network including an intelligent dynamic switch (IDS), the IDS comprising:
an A/D converter for digitizing the reverse RF signals and for providing the digital signals to the data buffer and the carrier detect circuit;
a data buffer for delaying the digital signals by a predetermined timeframe;
a carrier detect circuit coupled to the A/D converter for receiving the digital signals and for detecting the presence of at least one RF carrier signal within the predetermined timeframe; and
an enable switch that is controlled by the carrier detect circuit for allowing the delayed digital signals to be transmitted along with the at least one RF carrier signal; and
a D/A converter coupled to the enable switch for converting the digital signals back to reverse RF signals,
whereby controlling the transmission of the reverse RF signals reduces the amount of ingress noise signals in the reverse path of the broadband communications network.

8. The broadband communications network of claim 7, wherein the carrier detect circuit detects the presence of the at least one RF carrier signal by determining when power level values associated with the reverse RF signals is above a threshold value for the predetermined timeframe.

9. The broadband communications network of claim 7, wherein the IDS further comprises:
a first filter having a high pass filter and a low pass filter, the high pass filter for isolating forward RF signals, and the low pass filter for receiving the reverse RF signals provided by the enable switch; and
a second filter having a high pass filter and a low pass filter, the high pass filter coupled to the high pass filter of the first filter for providing the forward RF signals to the forward path, and the low pass filter for isolating the reverse RF signals and for providing the reverse RF signals to the IDS.

10. In a broadband communications network having forward and reverse paths for transmitting forward and reverse signals, respectively, the reverse signals including power level values and ingress signals, the broadband communications network including a distribution tap, the distribution tap including:
a first diplex filter having a high pass filter and a low pass filter, the high pass filter for isolating the forward signals, and the low pass filter for isolating the reverse signals;
forward path elements coupled to the high pass filter of the first diplex filter for processing;
a second diplex filter having a high pass filter and a low pass filter, the high pass filter coupled to the forward path elements for providing the processed forward signals to the forward path, and the low pass filter for receiving reverse signals;
an intelligent dynamic switch (IDS) coupled to the low pass filter of the second diplex filter, the intelligent dynamic switch comprising:
detecting means for detecting when at least one reverse carrier signal is present in the reverse signals;
delaying means for delaying the reverse signals; and
a switch controlled by the detecting means for releasing the delayed signals upon detection of the at least one reverse carrier signal; and
reverse path elements coupled to the IDS for processing and for providing the processed reverse RF signals to the low pass filter of the first filter,
wherein upon detection of the at least one RF carrier signal, the reverse RF signals are provided to the reverse path elements.

11. The distribution tap of claim 10, wherein the IDS further comprises:
digitizing means for converting the reverse signals to digital signals, and for providing the digital signals to the detecting means and the delaying means; and
converting means coupled to the switch for converting the digital signals back to the reverse signals.

12. The distribution tap of claim 11, wherein the detecting means is a digital carrier detect circuit.

13. The distribution tap of claim 12, wherein the digital carrier detect circuit detects the presence of the at least one reverse carrier signal by determining whether the power level values exceed a threshold value within a predetermined period of time.

14. A broadband communications network having forward and reverse paths for transmitting forward and reverse signals, respectively, the reverse signals having power level values and ingress signals, the broadband communications network comprising:
a plurality of intelligent dynamic switches (IDSs), each IDS comprising:
detecting means for detecting when at least one reverse carrier signal is present in the reverse signals;
delaying means for delaying the reverse signals; and
a switch controlled by the detecting means for releasing the delayed signals upon detection of the at least one reverse carrier signal,
wherein the plurality of intelligent dynamic switches blocks the ingress signals from further transmission upstream in the reverse path, thereby significantly reduces the ingress signals that are transmitted to a headend facility.

15. The broadband communications network of claim 14, wherein each IDS further comprises:
an A/D converter for digitizing the reverse signals prior to the detecting means; and
a D/A converter coupled to the switch for providing reverse signals in accordance with the received delayed digital signals.

16. The broadband communications system of claim 15, wherein the detecting means is a digital carrier detect circuit.

17. The broadband communications system of claim 14, wherein the digital carrier detect circuit detects the presence of the at least one reverse carrier signal by determining whether the power level values exceed a threshold value.

18. The broadband communications network of claim 14, wherein the plurality of IDSs are located in various locations in the reverse paths.

19. The broadband communications network of claim 14, wherein a number of the plurality of IDSs is located in a communications device, wherein the communication device is one of a distribution tap and one of an RF amplifier.
